(19) United States
(12) Patent Application Publication
(10) Pub. No.: US 2010/0220755 A1
(43) Pub. Date: Sep. 2, 2010

(54) SPECTRALLY TUNABLER LASER MODULE

(75) Inventors: Fuchs Frank, Denzlingen (DE); Rudolf Moritz, Denzlingen (DE); Christoph Wild, Denzlingen (DE); Eckhard Woerner, Freiburg (DE)

Correspondence Address: MARSHALL & MELHORN, LLC, FOUR SEAGATE - EIGHTH FLOOR, TOLEDO, OH, 43604, US

(73) Assignee: Fraunhofer-Gesellschaft Zur Foerderung Der Angewandten Forschung E.V., Munich (DE)

(21) Appl. No.: 12/733,242

(22) PCT Filed: Aug. 14, 2008
(86) PCT No.: PCT/EP2008/006703

§ 371 Date: May 3, 2010

(30) Foreign Application Priority Data
Aug. 20, 2007 (DE) 10 2007 039 219.4

(51) Int. Cl. H01S 5/024; H01S 5/34; H01S 3/04

(52) U.S. Cl. 372/36; 372/43.01; 372/34; 372/45.01

(57) ABSTRACT

The present invention relates to a laser module, comprising a flat substrate basis with a mounting region and with at least one heat conducting region adjoining the mounting region, one heating element arranged in the mounting region and one temperature sensor element arranged in the mounting region.

This invention relates to a spectrally tunable laser module, to a method for the operation of such a laser module and to applications of such a laser module. Spectrally tunable laser modules are used primarily in the field of the analysis of gases, fluids and/or surfaces.

In the field of the analysis of gases, fluids and surfaces, laser-assisted spectroscopic measurement methods are being used in an increasingly broad range of applications. One established field of activity represents the analysis of tracer gases by means of single-mode semiconductor lasers. This field of activity utilizes the variation of the emission wavelength of the laser with electric pumping. The injection of a current pulse into the active layer of the semiconductor laser leads to a heating and thus to a shift of the laser wavelength on the order of magnitude of approximately one wave number, i.e. in the average infrared spectral range of less than one per thousand. For lightweight molecules with low widths of the spectral line and a correspondingly narrow emission characteristic of the laser, this is sufficient and can be used for the high-sensitivity chemically specific sensor technology. This method is the prior art and is designated Tunable Diode Laser Spectroscopy (TDLAS) in English.

On the other hand, heavy organic molecules with a more complex construction have spectra in the infrared spectral range with significantly broader characteristic absorption bands. The half bandwidths are typically 10 to 30 wave numbers, i.e. far above the tuning range of the conventional laser spectroscopy described above. In the prior art, such large tuning ranges require significantly more complex technologies, such as an external cavity laser (ECL), for example, or frequency mixing methods of the type that are used, for example, in an optical parametric oscillator (OPO system).

With the conventional TDLAS technology, the scanning of such a broad absorption line is not possible and thus the reliability of a measurement with regard to the chemical species and cross-sensitivities with other substances is severely limited.

To expand the tuning range of semiconductor lasers, consideration could given to operating the lasers with higher currents to achieve a greater temperature shift. The heating of the active layer of a semiconductor laser beyond the injection current has limits, however. Theoretically by means of a very high injection current, a very strong heating can be achieved, although very high currents in a semiconductor laser are generally accompanied by unsuitable spectral characteristics. The mode characteristic is generally very complex and the noise conditions are unfavorable. High currents can also cause uncontrollable local overheating in the component which can ultimately lead to its destruction. For example, in the presence of high currents in the area of the laser facets, temperatures that are higher than in the volume of the laser occur, which can lead to total failure.

The object of this invention is therefore to make available a laser module which makes it possible to significantly expand the tuning range of a laser operated with the laser module or of a laser of the laser module compared to the prior art. An additional object of the invention is to make available a laser module with which a fast and accurate control of the corresponding tuning is possible, and with which a high uniformity across the tunable range can be achieved.

The invention teaches that this object is achieved by a laser module described in claim 1. Additional advantageous embodiments of the laser module claimed by the invention are described in the dependent claims 2 to 22. This invention also describes a corresponding method for the operation of the laser module (claims 22 and 23), as well as applications (claim 24).

This invention is described below, initially in general terms. The general description is followed by one concrete exemplary embodiment. The individual features of the concrete exemplary embodiment claimed by the invention can thereby occur in the context of this invention not only in a combination of the type that occurs in the specific advantageous exemplary embodiment, but also as they are or can be realized or used in any other possible combinations in the context of the invention.

The basic teaching of this invention is to realize the laser module so that the temperature variation of the laser (and the related shift of the emission wavelength of the laser) can occur independently of the injection conditions of the laser. With a decoupling of the type claimed by the invention, compared to the heating of the laser via the injection current (as with the TDLAS technology of the prior art, for example), a significantly greater temperature shift of several 100 K becomes possible (in the following example, more than 200 K was achieved). The invention teaches that this increase is possible without introducing any additional thermal load into the active layer of the laser. This invention thereby makes available a laser module in which the temperature of the semiconductor laser located on the laser module can be varied and/or modulated very rapidly by means of the diamond submount of the laser module. A decisive aspect is thereby the adjustment of a rapid temperature increase in combination with a high temperature swing. As a result of this temperature modulation which is made possible by the invention, it becomes possible to tune the wavelength of the laser in a very short time. The laser module claimed by the invention is realized so that it is possible to modulate the temperature of the laser or of the laser chip independently of the laser current or decoupled from the injection conditions of the laser at high speed (in particular at more than 1000 K/s) and/or with a large swing (in particular more than 100 K). Thus a significantly greater tuning range is achieved than is possible with spectrally tunable lasers of the prior art. Additional advantages of this invention are described in greater detail below with reference to one exemplary embodiment.

The invention teaches that a laser module is made available that has a flat substrate base (which is preferably realized from a single material, in particular diamond), whereby this base is generally realized in the form of an oblong, flat substrate base (ratio of length to width advantageously >5) and is divided into a mounting area and a least one additional thermal conduction area adjacent to this mounting area. In the mounting area on the flat substrate base are both a heating element and a temperature sensor element.

In one particularly advantageous embodiment of the invention which is described in greater detail below, in the thermal conduction area there are a plurality of notches or saw cuts that run all the way through the substrate base perpendicularly to the plane of the surface, so that a meandering thermal resistance element is realized in this thermal conducting area. It is particularly advantageous for a laser module claimed by the invention to have two adjacent thermal conducting areas on two opposite sides of a central mounting area, in each of which thermal conducting areas a meandering thermal resistance element of this type is formed. One or two contact surface areas are therefore advantageously adjacent to the end or ends of the flat substrate basis farther from the mounting area in the respective thermal conducting area(s). A contact surface area of this type, which is advantageously also realized in the form of part of the flat substrate base, can then be used as a contact surface with an external heat sink. If, like the mounting area, it is realized in the form of a part of the flat substrate base, a contact surface area of this type advantageously has the same thermal conductivity as the mounting area.

It is particularly advantageous if a material is selected for the flat substrate base that has a thermal conductivity of greater than 1,000 W/(K*m). Diamond is particularly well suited for this purpose.

As a result of the particularly advantageous combination of such a material with high thermal conductivity with the division claimed by the invention into a mounting area (in which both the heating element and the temperature sensor element are located and in which the laser is also then bonded) and the neighboring thermal conduction area(s) as well, as the advantageous realization of corresponding notched areas or thermal resistance elements in the thermal conductivity area(s), not only can a very high thermal homogeneity be achieved in the area of the contact surface of the laser (mounting area)_{;} but the temperature variation can also be controlled very quickly, so that the laser can be very rapidly tuned across the desired spectral range. For this purpose, in particular the heating element, the temperature sensor element and the laser are advantageously located as close as possible to one another in the mounting area of the flat substrate.

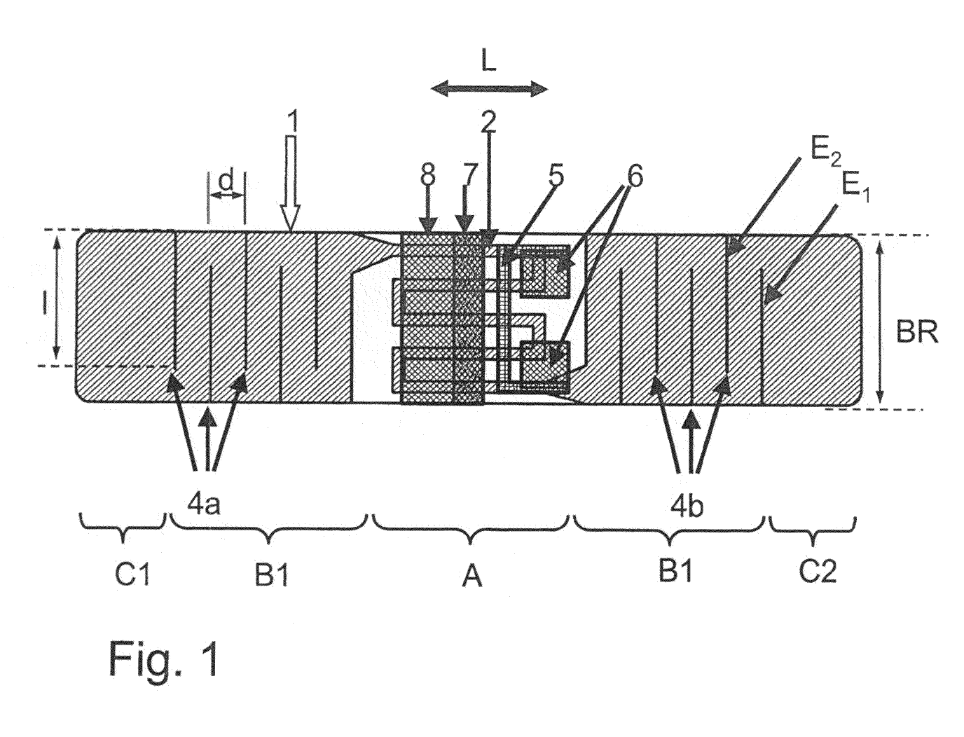

The invention is described in greater detail below with reference to the special exemplary embodiment illustrated in the accompanying FIGS. 1 to 7, in which:

FIG. 1 shows one advantageous embodiment of a laser module claimed by the invention.

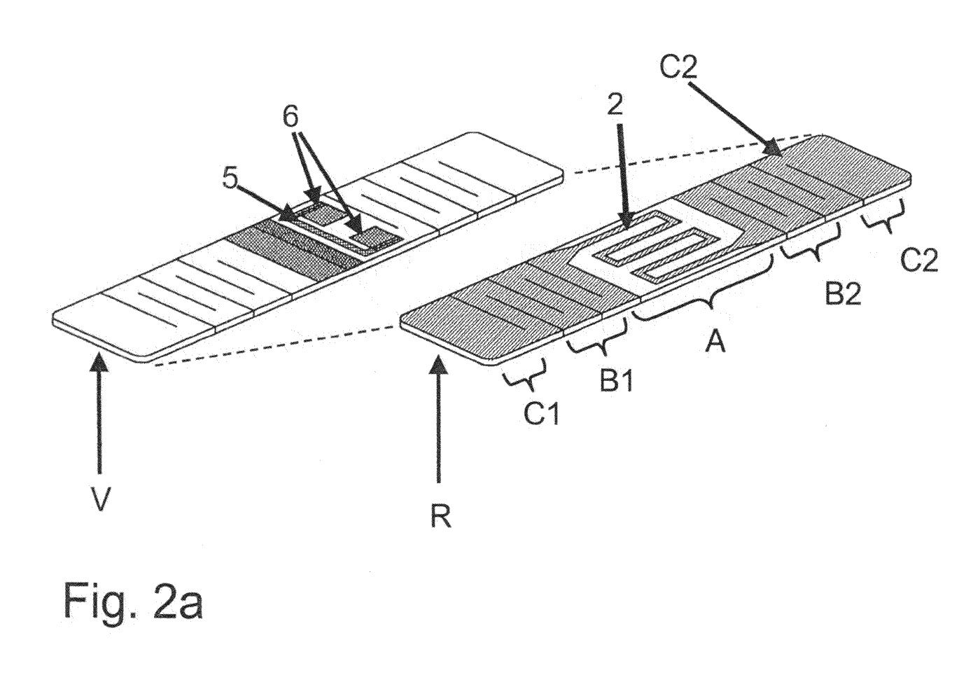

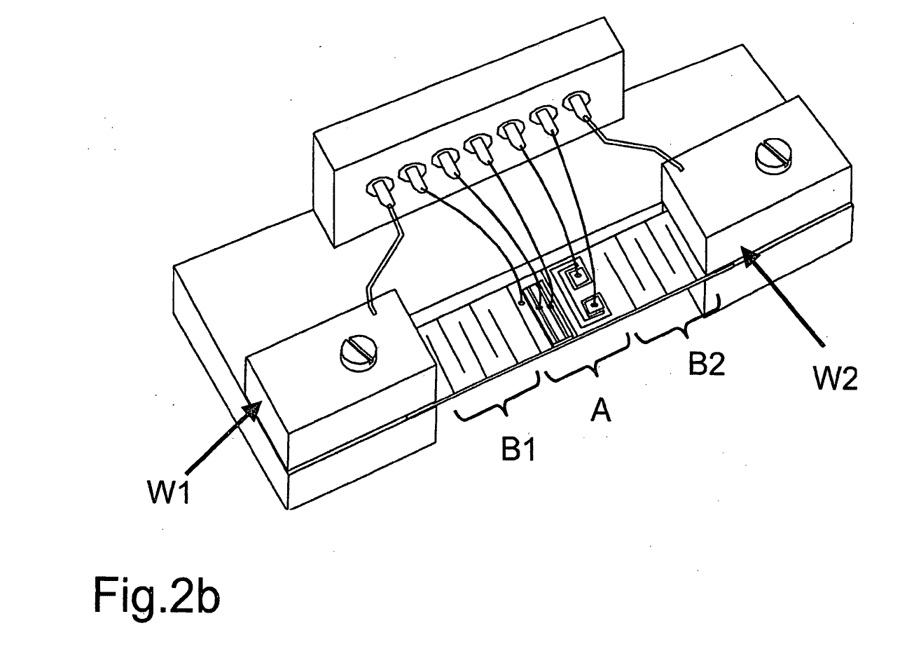

FIG. 2a shows a view V of the front surface and the a view R of the rear surface of the substrate base 1 with the temperature sensor element mounted (in the laser module illustrated in FIG. 1).

FIG. 2b shows the corresponding module from FIG. 1 with the mounted and bonded laser and with thermally connected heat sinks.

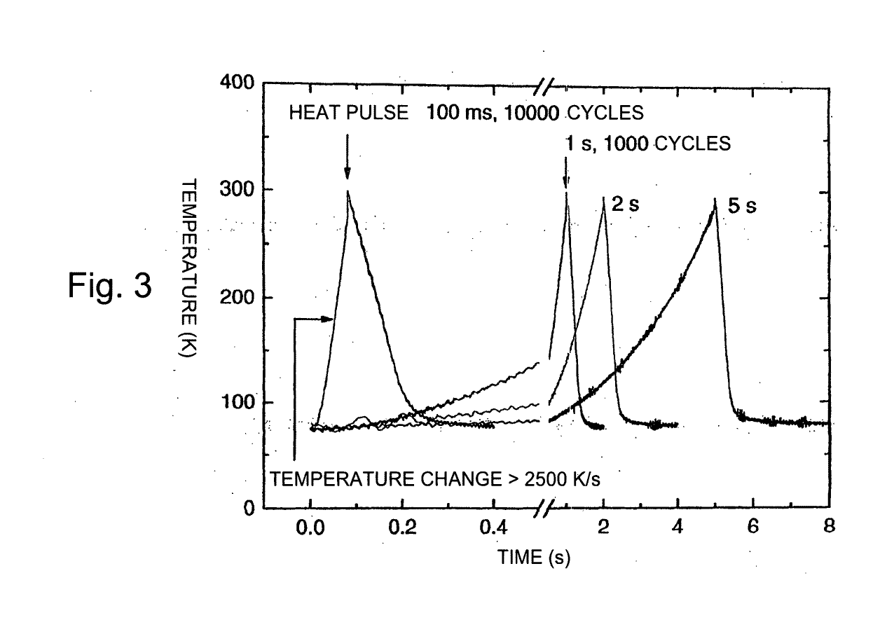

FIG. 3 shows the temperature curve of the laser module illustrated in FIG. 1 with various durations of heating pulses.

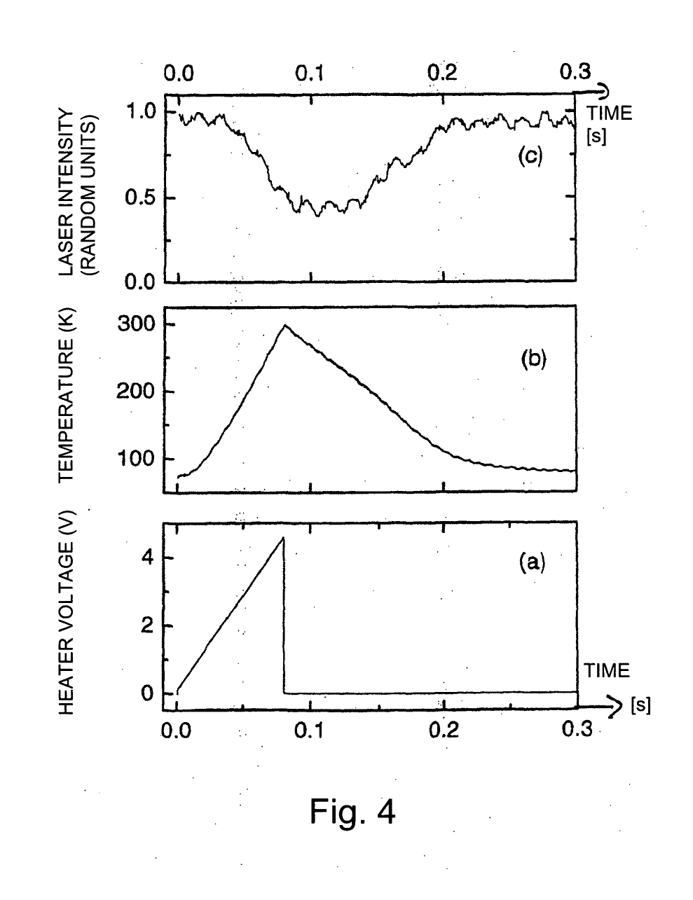

FIG. 4 shows the curve over time of the voltage at the heating element or heating resistance, the temperature at the temperature sensor element and the laser intensity during a 100 ms single pulse of the heating voltage.

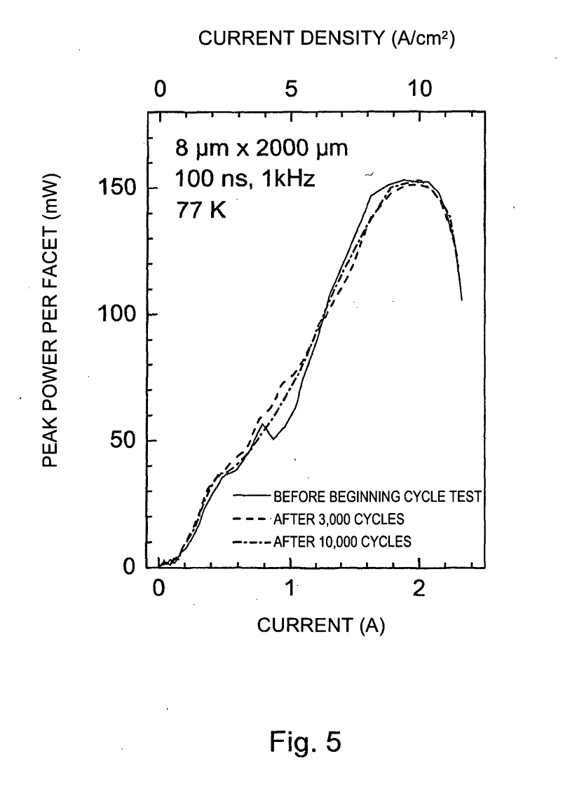

FIG. 5 shows output-current characteristics of the laser used together with the laser module illustrated in FIG. 1.

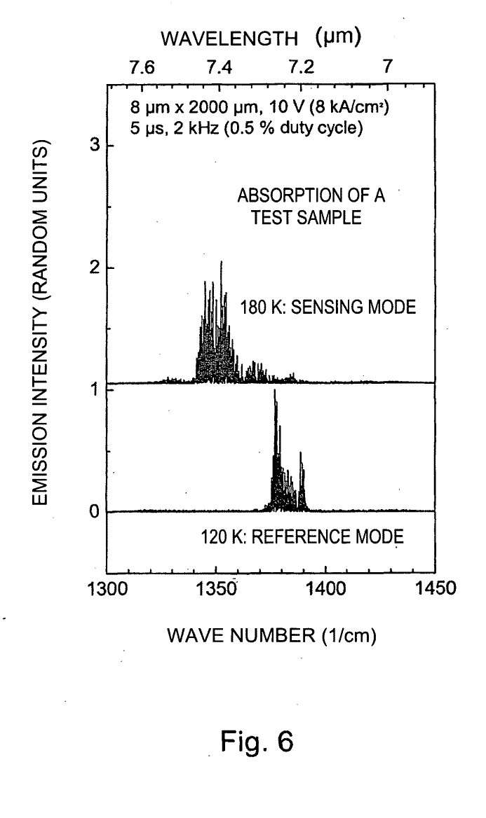

FIG. 6 shows the emission characteristic of a quantum cascade laser used in connection with the module illustrated in FIG. 1.

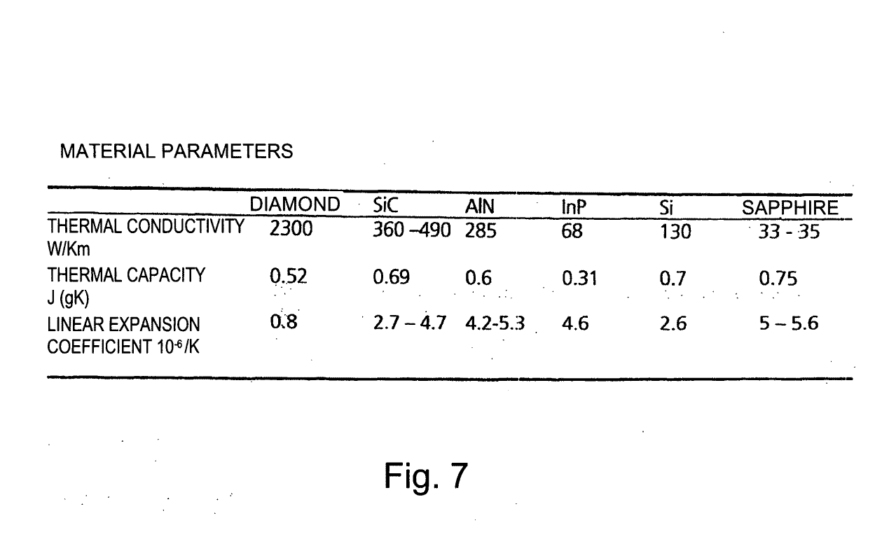

FIG. 7 shows different materials that can be used for the flat substrate.

FIG. 1 illustrates one advantageous exemplary embodiment of a laser claimed by the invention. The laser module has a flat substrate base 1 made of diamond, which has a thickness of 0.1 mm in the direction perpendicular to the surface plane shown here, and a length-to-width ratio which in this case is 5 (length in direction L, width in direction BR). The flat substrate base 1 is then divided as follows into a total of five segments along the longitudinal direction L. In a central section or area, the mounting surface A, both sides of the mounting surface or of the mounting area A and adjacent to it, respective thermal conductivity areas (areas B1 and B2) and adjacent to the thermal conductivity areas B1 and B2, on the side of the thermal conductivity areas facing away from the mounting area A, contact surface areas C1 and C2, which therefore form the respective terminal areas of the substrate base). The mounting area A and the two thermal conductivity areas B1 ad B2 are thereby approximately equal in the longitudinal direction L; the two contact areas C1, C2 each have approximately half the length of the areas B1 and B2 respectively. The areas listed above thereby each comprise the illustrated surface segment on the upper side of the substrate base 1 and the corresponding surface segment located exactly on the opposite underside of the substrate base 1. As described in greater detail below, additional elements of the laser module claimed by the invention are located in the mounting area A on its upper side and on its underside and/or on the corresponding upper side segment and underside segment of the substrate base.

The segments B1 and C1 on one hand and the segments B2 and C2 on the other hand are thus located on opposite sides of the mounting area A (all the above mentioned segments in a line). It is also possible, of course, to locate the segments C1 and B1, for example, not offset by 180° with respect to the segments B2 and C2, but at a 90° angle (arrangement in the shape of an “L” with the mounting area A at the articulation point of the “L”). As described in greater detail below, the illustrated laser module or its substrate base is made of a material that has high thermal conductivity (diamond), in which the thermally conducting areas B next to the mounting area A are realized with reduced thermal conductivity. In the vicinity of the mounting surface A, the heating element and the temperature sensor element are then located by means of front-side and/or back-side metallizations. Likewise, in the area A, a laser bond metallization is provided so that the semiconductor laser is also brought into contact with the substrate base in the area A. In the contact surface areas C, the substrate base is realized so that it has the same thermal conductivity as in mounting area A. In these areas C, heat sinks (e.g. copper bodies or similar bodies, including liquid-driven heat sinks or similar bodies are possible, as the technician skilled in the art will be aware. In the area A in which both the laser mounting surface as well as the laser, the heating element and the temperature sensor are located, the flat substrate base is prepared to that it is homogeneous and unstructured, which results in high thermal conductivity. With the diamond module with dimensions 3×13 mm² and a thickness of 0.1 mm used in this example, the non-contacting surface B (10×3 mm³) has a thermal capacity of 5.5×10⁻³J/K (at 300 K). The value for the heat sink W should be higher by at least a factor of 10. The factor 20 has been selected here (results in 0.1 J/K for the heat sink W).

A temperature gradient toward the heat sink or toward the contact surface areas C can now be established by means of the areas B with reduced thermal conductivity. In the areas B, the thermal conductivity is reduced in a controlled manner by means of notches (saw cuts) cut into the material of the substrate base 1. The module once again has the maximum thermal conductivity in the area of the contact surfaces C which create the contact with the heat sink. In this case, diamond is used as the materials for the substrate base 1 as described above, although other materials such as SiC or AlN can also be used (see also table in FIG. 7).

A temperature sensor element 5 in the form of a C-shaped metallization is installed in the mounting area A on the upper side of the module shown in FIG. 1. This temperature sensor element 5 is electrically connected with two electrical contacts 6, by means of which a temperature sensor head (e.g. in the form of a resistance measurement unit) can be connected. Also on the front side shown here, in the mounting area A there is an additional metallization, the laser bond metallization 8. This metallization is used to bond contacts of the semiconductor laser used by means of the solder deposit 7 which is also located in the area A. The semiconductor laser used (not shown here) is thus also located in the area A and is in immediate proximity to the temperature sensor element (and also to the heating element, which is described in greater detail below).

On the reverse side R opposite to the front side V shown here (see FIG. 2a) of the substrate base 1, also in the mounting area A and thus in immediate proximity to the elements 5 to 9, the heating element 2 is realized in the form of a meander heating resistance (which is also realized in the form of a metallized layer). The heating element 2 is not shown opaquely in the figure, but is only indicated by means of its edges, to show that it is on the opposite surface side R from the elements 5 to 8. The heating element 2 also has two electrical contacts (not shown here), by means of which a current source can be connected to the heating element 2.

Each of the two thermal conduction areas B1 and B2 is then realized as follows: Viewed in the longitudinal direction L, notches are introduced into the substrate base 1 in alternation (i.e. alternating from both lateral edges, in this figure therefore from the top longitudinal narrow side and the bottom longitudinal narrow side). These notches (e.g. the notches E1 and E2) are thereby cut all the way through the thickness (perpendicular to the plane of the paper) of the substrate (e.g. they are cut all the way through the substrate layer). Viewed in the longitudinal direction, neighboring notches E1, E2 are thereby separated by the distance d. The notch length, i.e. its depth viewed in the direction of the width BR, is 1. The length 1 is hereby significantly greater than the distance d, and the ratio here is approximately V2=1/d=4. Because the width BR of the substrate 1 is only insignificantly greater than 1 (here approximately 1.25*1) and because six notches E were made in each of the areas B1 and B2, a meandering thermal resistance element is thereby formed (resistance elements 4a and 4b) in each of the areas B1 and B2. The essential feature in this case is therefore on one hand that the above mentioned ratio V2=1/d has a minimum value and that neighboring segments are cut in respectively from both sides (viewed in the longitudinal direction L) so that the above mentioned meandering path results for the thermal conduction, i.e. the path of is significantly longer than the dimension of the areas B1 and B2 viewed in the longitudinal direction. The geometry described above is hereby realized so that in the illustrated case the ratio V1=W_{A}/W_{B} of the thermal conductivity W_{A} of the mounting area A and the thermal conductivity W_{B} of a thermally conducting area B1, B2 is approximately 30.

Also decisive is the compact, integrated arrangement of the elements 5 to 8 in the mounting area A. The decisive variables in this regard are the two ratios v3 and v4 as follows. Let A_{H} be the average dimension of the heating element in the surface plane (if the heating element 2 can be considered in a first approximation to be square, it corresponds to the length of one side of the square). Let A_{T} be the corresponding average dimension of the temperature sensor element (if this element has, for example, the approximate shape of a circle in the surface plane, this dimension equals the diameter of the circle). If we the take the average of these two dimensional values A_{HT} and place it in a ratio to the distance a_{HT} between the heating element and the temperature sensor element, the two elements 2, 5 must be arranged so that the ratio v3=a_{HT}/A_{HT} is as small as possible. The distance is hereby defined as the distance between the (geometric) centers of gravity of the two elements 2, 5 in the surface plane. V3 is approximately 0.8 here. Likewise, the ratio v4=a_{HL/}A_{HL} can be defined from the distance a_{HL} between the heating element on the one hand and the laser bond metallization 8 (or the laser) on the other hand and by the correspondingly determined average dimension A_{HL} of the heating element and of the laser bond metallization (or of the laser). The distance is here again defined by means of the centers of gravity and in the surface plane. This value should also be selected so that it is as small as possible (here it is approximately 0.5).

On the upper side of the substrate base 1, a gold metallization (laser bond metallization 8) is therefore applied in the center A and is used for the mounting of a semiconductor laser by means of soldering (see also FIG. 4). The rear contacts of the laser are bonded to this gold surface. On the reverse side of the substrate base 1 is an additional metallization (heating element 2), the shape (meandering) of which is such that a simple, fast and selective heating of the center mounting surface A becomes possible. The thermal resistance of the mounting surface A relative to the lateral contact surfaces (contact surfaces C1 and C2) is defined by the notches E in the thermal conduction areas B1 and B2. If the substrate base in the area C is then placed in contact with a heat sink W (see FIG. 4), the temperature can be defined and rapidly increased by heating the mounting surface A of the laser. The metallization 5 and the temperature sensor element 5 on the front side of the module make possible a constant control of the laser temperature (in the simplest case by means of a resistance measurement).

FIG. 2 shows, in FIG. 2a, a concrete realization of a laser module claimed by the invention in the front-side view V and back-side view R with the heating metallization and the heating element 2 on the back side R and of the temperature metallization and the temperature sensor element 5 on the front side V.

FIG. 2b is a detail, although it shows only the mounting area A with the thermally conductive areas B1 and B2 located alongside it. The contact areas C1 and C2 are here concealed by the heat sinks (copper bodies) W1 and W2. The figure also shows the bonded laser. The lateral copper contact surfaces of the heat sinks W1, W2 form the contact of the laser to the heat sinks.

The optimum overall performance of the laser module is achieved by using diamond as the material for the flat substrate base 1. The use of diamond is advantageous primarily for the rapid temperature equalization in the mounting area A between the heating element 2, the flat substrate base 1 and temperature sensor element 5, on account of the high thermal conductivity. Defined temperature variations can therefore be achieved very quickly. Using the diamond module claimed by the invention, rates of more than 2,500 K/s can be achieved with temperature swings between 77 K and 300 K (see also FIG. 5, which illustrates the curve of the temperature of a laser module claimed by the invention with a diamond substrate base and with various durations of a heat pulse applied to the heating element 2 (the fastest rate of more than 2,500 K/s was achieved with a heat pulse 100 ms long)).

FIG. 4 shows the curves of the heating voltage on the heating resistance 5 (a), the temperature at the integrated sensor (in the mounting area A) (b) and the laser intensity (c) during a 100 ms heater pulse. The decrease in the temperature after the heater voltage is turned off takes someone longer than the heating. The rate of increase is thereby a function of the thermal resistance in the thermal conductivity area B and the heating power. The decay characteristic can also be set by means of the thermal resistance. The thermal resistance is defined by the number and configuration of the lateral notches in the diamond substrate (FIG. 1). In this example, the thermal conductivity in Zone B (see FIG. 1) has purposely been reduced by a factor of 30. Therefore only a very low heat output is necessary to raise the temperature from 77 K to 300 K. The maximum heat output at the end of the heater pulse after 80 ms is only approximately 300 mW. The thermal conductivity reduced in this manner limits the time of the temperature decrease after the heater is turned off from 300 K back to the base temperature of 77 K to approximately 150 ms (FIG. 4(b)). This response can be optimized by modification of the notches in the area B. Smaller notches increase the thermal conductivity. In other words, more heat output is required for the same temperature increase. With this arrangement, the temperature decrease is achieved more rapidly after the heater is turned off.

FIG. 4(c) shows the intensity curve of the laser emission. As expected, the laser intensity is reduced by slightly less than one-half during the change from 77 K to room temperature. The slight oscillations of the intensity are the result of variations of the mode distribution as a result of the shift of the laser wavelength.

In the operation of the module described here, note should be taken of the different thermal expansion rates of the materials used. The thermal expansion rate of diamond is less than that of the III-V semiconductor of the laser used in the illustrated example (see FIG. 7). In the design, the thermally induced distortion between the diamond and the semiconductor laser must be kept as small as possible. In addition, the solder connection between the laser and the module must be sufficiently stable. To keep the distortion and thermal capacity minimal, the smallest possible laser chip must be used. The rate of temperature variation must also be matched to the time that the laser chip requires to assume the most uniform possible temperature distribution. Otherwise additional internal stresses would be generated, which could lead to the destruction of the laser chip.

Load tests with an active laser assembly were performed in the operating mode described above. When a 2000 μm×1000 μm laser chip was used, on which a 8 μm×2000 μm quantum cascade laser (QC laser) was located, 10,000 temperature cycles could be performed between 77 K and 300 K the laser, which was in constant operation throughout, did not suffer any damage.

FIG. 5 shows the optical output of the laser over the injection current (output-current characteristic of the laser, measured at 77 K). 1: Before the beginning of the cycle tests, 2: after 3,000 temperature cycles, 3: after an additional 7,000 cycles. Slight variations of the characteristic curve are observed in the medium current range. Here, different lateral modes are stimulated, the distribution of which obviously varies slightly. The maximum output and in particular the threshold current have not changed, within the limits of measurement accuracy, even after a total of 10,000 cycles.

The invention teaches a novel concept which makes possible the expansion of the spectral tuning range of semiconductor lasers in optical spectroscopy. A QC laser constructed on the diamond module is operated at 180 K and 120 K alternately. The period of the complete heating and cooling cycle is 1 s. As illustrated in the emission characteristic shown in FIG. 6, the laser emission at 180 K exactly matches the absorption of a complex molecule of a test substance with a broad absorption band centered at 1350 cm⁻¹. At 120 K, the emission characteristic shifts to 1380 cm⁻¹ (a reference measurement can be performed at 120 K). With a suitable optical method, the absorption can be measured during the half period of the temperature cycle at 180 K (sensing mode), whereby in the second half period, a reference imaging becomes possible (reference mode) because the substance does not absorb in the spectral range around 1380 cm⁻¹. Thus a spectrally differential measurement method becomes possible, in which the individual measurement can lie approximately in the range of time between 100 ms and one second. The laser was operated at a current density of 8 kA/cm² at a pulse length of 5 μs and a repetition rate of 2 kHz.

Finally, FIG. 7 shows the different material parameters of typical materials that can be used as the substrate base of the laser module claimed by the invention.

1-28. (canceled)

29. A laser module comprising
a flat substrate base with a mounting area and with at least one thermally conductive area adjacent to the mounting area,
a heating element located in the mounting area, and
a temperature sensor element located in the mounting area, wherein a meander-shaped thermal resistance element is realized in at least one of the thermally conductive areas by means of at least two of the notches that are cut completely through the substrate base perpendicular to the surface plane.

30. The laser module according to claim 29, wherein the notches in the meander-shaped thermal resistance element and/or the substrate base are realized and/or are oriented so that the ratio v1=W_{A}/W_{B} of the thermal conductivity W_{A} of the mounting area (A) and the thermal conductivity W_{B} of the thermally conducting area is greater than 10 or greater than 20 or greater than 30 or greater than 50.

31. The laser module according to claim 29, wherein the meander-shaped thermal resistance element has at least four or at least six or at least eight notches, and/or the ratio v2=1/d of the notch length 1 and notch distance d between two neighboring notches when there are at least two notches of the meander-shaped thermal resistance element is greater than 1 or greater than 1.5 or greater than 2 or greater than 3 or greater than 5.

32. The laser module according to claim 29, wherein the substrate base, the mounting area, the thermal conductionarea, the heating element and/or the temperature sensor element is/are located and/or realized so that the temperature of a laser located in the mounting area can be regulated independently of the laser current or the injection of a current pulse into the active layer of the laser at a rate of greater than 500 K/s or greater than 1000 K/s and a swing greater than 50 K or greater than 100 K.

33. The laser module according to claim 29, wherein the substrate base has two thermally conductive areas adjacent to the mounting area.

34. The laser module according to claim 33, wherein these two thermal conduction areas are adjacent on opposite sides to the mounting area.

35. The laser module according to claim 33, wherein a meander-shaped thermal resistance element is realized in each of the two thermal conduction areas.

36. The laser module according to claim 29, wherein the substrate base is made of exactly one material.

37. The laser module according to claim 36, wherein the material is diamond, SiC, AlN, InP, Si or sapphire.

38. The laser module according to claim 29, wherein the substrate base has a thermal conductivity of greater than 200 W/(m*K) or greater than 400 W/(m*K) or greater than 1000 W/(m*K) or greater than 2000 W/(m*K).

39. The laser module according to claim 29, wherein the heating element and the temperature sensor element are located on one and the same surface side of the mounting area of the flat substrate base or the heating element and the temperature sensor element are located on the opposite surface sides of the mounting area of the flat substrate base.

40. The laser module according to claim 29, wherein the ratio v3=a_{HT}/A_{HT} of the distance a_{HT} between the heating element and temperature sensor element and of the determined average dimension A_{HT} of the heating element and of the temperature sensor element is less than 1.5 or less than 1 or less than 0.5 or less than 0.5 or less than 0.1.

41. The laser module according to claim 29, wherein the heating element has a metallization (heating metallization) which is located in the mounting area immediately adjacent to exactly one surface side of the substrate base.

42. The laser module according to claim 29, wherein the heating metallization is meander-shaped and/or the heating element has two electrical contacts for connection to a current source.

43. The laser module according to claim 29, wherein the temperature sensor element has a metallization (temperature sensor metallization) which is located in the mounting area immediately adjacent to exactly one surface side of the substrate base.

44. The laser module according to claim 29, wherein the temperature sensor element also has two electrical connection contacts.

45. The laser module according to claim 29, comprising a laser, single-mode semiconductor laser or quantum cascade laser located in the mounting area.

46. The laser module according to claim 29, wherein on one hand the laser bond metallization and/or the laser and on the other hand the temperature sensor element are located on opposite surface sides of the mounting area of the flat substrate base.

47. The laser module according to claim 29, wherein the ratio v4=a_{HL}/A_{HL} of the distance a_{HL} between the heating element on one hand and the laser and/or laser bond metallization on the other hand and of the determined average dimension A_{HL} of the heating element and of the laser and/or of the laser bond metallization is less than 1.5 or less than 1 or less than 0.5 or less than 0.1.

48. The laser module according to claim 29, wherein the substrate base has at least one contact surface area on the side opposite the mounting area that is adjacent to at least one of the thermally conductive areas in this thermal conduction area.

49. The laser module according to claim 29, comprising a heat sink which is thermally coupled with the contact surface area and/or is located adjacent to the contact surface area.

50. The laser module according to claim 49, wherein the heat sink is realized in the form of a solid body with a specific thermal capacity of greater than 0.1 J/K.

51. The laser module according to claim 29, wherein the thermal capacity of the mounting area and the thermal capacity of at least one of the contact surface areas are identical.

52. The laser module according to claim 29, wherein the substrate base has a thickness perpendicular to the surface plane of between 20 μm and 500 μm.

53. A method for the operation of a laser module, wherein at least one rising electrical voltage pulse is applied to the heating element of a laser module as recited in claim 29.

54. The method according to claim 53, wherein the electrical voltage pulse rises in a ramp and/or the electrical voltage pulse has a pulse length of between 10 ms and 500 ms or between 50 ms and 200 ms.

55. The method according to claim 53, wherein the electrical voltage pulse is realized so that the temperature of a laser located in the mounting area of the laser module is regulated independently of the laser current or the injection of a current pulse into the active layer of the laser at a range of greater than 500 K/s or greater than 1000 K/s and/or a swing of greater than 50 K or greater than 100 K.
